(19) United States
(12) Patent Application Publication
(10) Pub. No.: US 2022/0328443 A1
(43) Pub. Date: Oct. 13, 2022

(54) PACKAGE STRUCTURE AND FORMING METHOD THEREOF

(71) Applicant: CHIPMORE TECHNOLOGY CORPORATION LIMITED, Suzhou City, Jiangsu Province (CN)

(72) Inventor: HAO CHEN, Suzhou City, Jiangsu Province (CN)

(21) Appl. No.: 17/615,823

(22) PCT Filed: Nov. 3, 2020
(86) PCT No.: PCT/CN2020/126036

§ 371 Date: Dec. 1, 2021

(30) Foreign Application Priority Data
Dec. 30, 2019 (CN) 201911398017.6

(51) Int. Cl. H01L 23/00

(52) U.S. Cl. CPC H01L 24/13; H01L 24/11; H01L 2924/365; H01L 2224/11622; H01L 2224/1145; H01L 2224/11472; H01L 2224/13147; H01L 2224/13553; H01L 2224/13566; H01L 2224/13576; H01L 2224/13666

(57) ABSTRACT

The present invention discloses a package structure and a forming method thereof. The package structure includes a substrate and a redistribution layer. The redistribution layer includes a plurality of metal bumps distributed at intervals, at least the periphery of the metal bumps is covered with seed layers, and the seed layers of adjacent metal bumps are disconnected from each other. The seed layers of this embodiment have stable metallic characteristics, which may achieve effective protection of side walls of the metal bumps against metal-to-metal migration due to oxidation and corrosion of the metal bumps, thereby avoiding electrical leakage and failure of a chip and greatly increasing the reliability of the package structure.

### CROSS-REFERENCE TO RELATED APPLICATION

This application claims priority to Chinese Patent Application No. 201911398017.6, filed on Dec. 30, 2019, and entitled “PACKAGE STRUCTURE AND FORMING METHOD THEREOF” which is incorporated herein by reference in its entirety.

### TECHNICAL FIELD

The present invention relates to the field of packaging technologies, and in particular, to a package structure and a forming method thereof.

### BACKGROUND

In an integrated circuit packaging process, a redistribution layer (RDL) includes a plurality of metal bumps, The metal bumps are generally copper blocks. The spacing between copper blocks is very small, between about 10 to 20 urn, and is very thin and narrow. In addition, copper is active and susceptible to oxidation and corrosion, which may result in failure. When there is no effective protection measure on side walk of the copper blocks, the copper blocks are prone to oxidation and corrosion in a high temperature and high humidity environment and to metal migration in a narrow gap, which in turn results in electrical leakage and failure of a chip.

### SUMMARY

An object of the present invention is to provide a package structure and a forming method thereof.

For achieving one of the above inventive objects, an embodiment of the present invention provides a package structure, including a substrate and a redistribution layer, where the redistribution layer includes a plurality of metal bumps distributed at intervals, at least the periphery of the metal bumps is covered with seed layers, and the seed layers of adjacent metal bumps are disconnected from each other.

As a further improvement of an embodiment of the present invention, the seed layers include first seed layers, second seed layers, and third seed layers that are connected, the first seed layers are located at the periphery of the metal bumps, the second seed layers are located on a surface of the side of the metal bumps away from the substrate, the third seed layers are located on the substrate, and adjacent ones of the third seed layers are disconnected from each other.

As a further improvement of an embodiment of the present invention, the second seed layers enclose to form openings, so as to expose the metal bumps.

As a further improvement of an embodiment of the present invention, the seed layers are titanium layers.

For achieving one of the above inventive objects, an embodiment of the present invention provides a forming method of a package structure, including the steps of:

forming a redistribution layer on a wafer substrate, where the redistribution layer includes a plurality of metal bumps distributed at intervals;

forming seed layers at least at the periphery of the metal bumps, and disconnecting the seed layers of adjacent metal bumps from each other; and

cutting the wafer substrate to form a plurality of the package structures independent of each other.

As a further improvement of an embodiment of the present invention, the step of “forming seed layers at least at the periphery of the metal bumps” specifically includes:

coating a photoresist above the wafer substrate;

removing a part of the photoresist by exposing and developing processes to form a reserved photoresist, where the reserved photoresist is located at least between the plurality of metal bumps;

forming seed layers by a sputtering process, where the seed layers cover at least the periphery of the metal bumps; and

removing the reserved photoresist and the seed layers located at the reserved photoresist.

As a further improvement of an embodiment of the present invention, the step of “removing a part of the photoresist by exposing and developing processes to form a reserved photoresist” specifically includes:

placing a mask plate with a plurality of apertures above the photoresist;

illuminating the photoresist with light through the plurality of apertures to achieve exposure; and

removing a part of the photoresist by a developing process to form the reserved photoresist in an inverted trapezoidal shape.

As a further improvement of an embodiment of the present invention, the step of “coating a photoresist above the wafer substrate” specifically includes:

coating a photoresist above the wafer substrate, where the photoresist encapsulates the plurality of metal bumps.

As a further improvement of an embodiment of the present invention, the step of “removing a part of the photoresist by exposing and developing processes to form a reserved photoresist, where the reserved photoresist is located at least between the plurality of metal bumps” specifically includes:

removing a part of the photoresist by exposing and developing processes to form a reserved photoresist in an inverted trapezoidal shape, where the reserved photoresist includes a first reserved photoresist located between the plurality of metal bumps and a second reserved photoresist located on the side of the metal bumps away from the wafer substrate.

As a further improvement of an embodiment of the present invention, the step of “forming seed layers by a sputtering process, where the seed layers cover at least the periphery of the metal bumps” specifically includes:

forming seed layers above the reserved photoresist by a sputtering process, where the seed layers cover the periphery of the metal bumps, an area of the wafer substrate not covered by the first reserved photoresist, an area of the metal bumps not covered by the second reserved photoresist, and a surface of the side of the reserved photoresist away from the wafer substrate.

Compared with the prior art, the beneficial effects of an embodiment of the present invention are that the seed layers of an embodiment of the present invention have stable metallic characteristics, which may achieve effective protection of side walls of the metal bumps against metal-to-metal migration due to oxidation and corrosion of the metal bumps, thereby avoiding electrical leakage and failure of a chip and greatly increasing the reliability of the package structure.

### BRIEF DESCRIPTION OF THE DRAWINGS

FIG. 1 is a schematic diagram of a package structure according to an embodiment of the present invention;

FIG. 2 is a diagram of steps of a forming method of a package structure according to an embodiment of the present invention; and

FIGS. 3 to 8 are schematic diagrams of a flowchart of the forming method of the package structure according to an embodiment of the present invention.

### DETAILED DESCRIPTION

The present invention will be described in detail below with reference to embodiments shown in the accompanying drawings. However, these embodiments are not intended to limit the present invention, and changes of structures, methods or functions made by an ordinary person skilled in the art according to these embodiments are all encompassed within the scope of protection of the present invention.

In various illustrations of the present invention, for ease of illustration, some dimensions of structures or parts may be exaggerated with respect to other structures or parts, and therefore, are merely used for illustrating basic structures of the subject matter of the present invention.

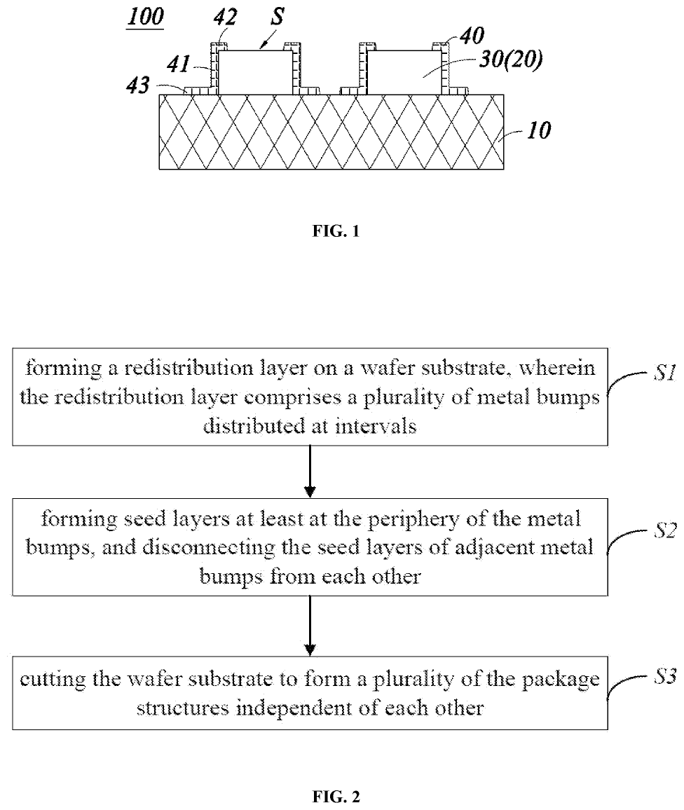

Referring to FIG. 1, it is a schematic diagram of a package structure 100 according to an embodiment of the present invention.

The package structure 100 includes a substrate 10 and a redistribution layer 20. The redistribution layer 20 includes a plurality of metal bumps 30 distributed at intervals. At least the periphery of the metal bumps 30 is covered with seed layers 40, and the seed layers 40 of adjacent metal bumps 30 are disconnected from each other.

Here, the redistribution layer 20 may include several metal layers and insulation layers that are arranged alternately. The metal layers are generally copper layers and include a plurality of metal bumps 30 distributed at intervals. The metal bumps 30 may subsequently be connected to the outside by a forming process such as a copper pillar, a placed ball, etc. It can be understood that in some embodiments, the substrate 10 may not be included, and the redistribution layer 20 is directly used as a substrate.

The seed layers 40 are UBM layers. Here, a titanium layer is taken as an example for the seed layers 40, but is not limited thereto.

It should be noted that by “at least the periphery of the metal bumps 30 is covered with seed layers 40”, it means that the seed layers 40 are formed at least at side walls of the metal bumps 30, and by “the seed layers 40 of adjacent metal bumps 30 are disconnected from each other”, it means that some of the seed layers 40 are located in a gap between adjacent metal bumps 30 and these seed layers 40 are disconnected from each other, avoiding a short circuit and thus failures.

Here, the seed layers 40 have stable metallic characteristics, which may achieve effective protection of the side walls of the metal bumps 30 against metal-to-metal migration due to oxidation and corrosion of the metal bumps 30, thereby avoiding electrical leakage and failure of a chip and greatly increasing the reliability of the package structure. Of course, in other embodiments, the seed layers 40 may also cover other areas.

In this embodiment, the seed layers 40 include first seed layers 41, second seed layers 42, and third seed layers 43 that are connected. The first seed layers 41 are located at the periphery of the metal bumps 30. The second seed layers 42 are located on a surface of the side of the metal bumps 30 away from the substrate 10. The third seed layers 43 are located on the substrate 10, and adjacent third seed layers 43 are disconnected from each other.

It should be noted that by “the third seed layers 43 are located on the substrate 10”, it means that the third seed layers 43 are located above the substrate 10, but is not limited to the fact that the third seed layers 43 are directly connected to the substrate 10, and the third seed layers 43 are actually connected to one end of the first seed layers 41 away from the second seed layers 42.

In addition, in this embodiment, the second seed layers 42 enclose to form openings S, so as to expose the metal bumps 30.

That is, the second seed layers 42 are located in a peripheral area of an upper surface of the metal bumps 30, a middle area of the upper surface of the metal bumps 30 is a bare area, and the second seed layers 42 do not cover the middle area.

It should be noted that the metal bumps 30 are generally made of copper materials. Copper has an electrical conductivity superior to titanium, that is, the metal bumps 30 have an electrical conductivity superior to that of the second seed layers 42. In some embodiments, it is also necessary to form the copper pillar, the placed ball, or the like on the metal bumps 30 subsequently, so as to enable connection to the outside. At this time, only by disposing a structure such as the copper pillar, the placed ball or the like in the middle area of the upper surface of the metal bumps 30, that is, directly connecting the structure such as the copper pillar, the placed ball or the like to the metal bumps 30, signal transmission between the metal bumps 30 and the structure such as the copper pillar, the placed ball or the like may be improved effectively, thereby improving the performance of the whole package structure 100.

It should be noted that the package structure 100 of this embodiment may further include other structures, such as a placed ball, a plastic package layer, or the like, and the finally formed package structure 100 may be a chip.

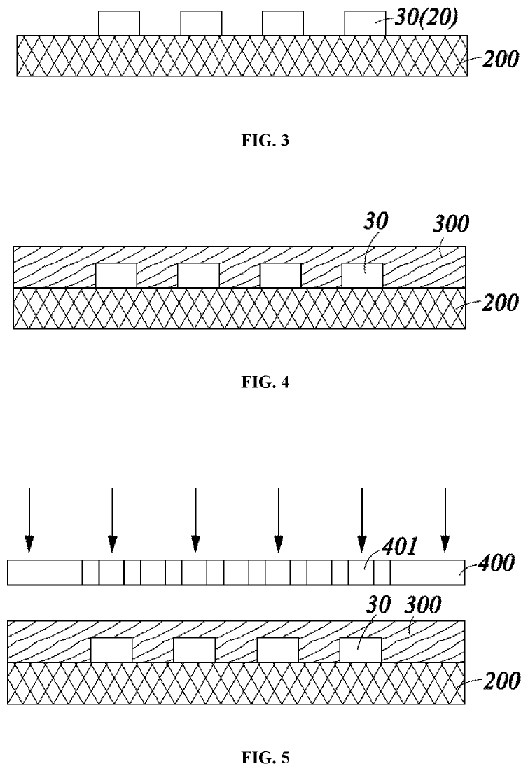

Referring to FIGS. 2 to 8, they are schematic diagrams of a forming method of the package structure 100 according to an embodiment of the present invention.

The forming method of the package structure 100 includes the following steps:

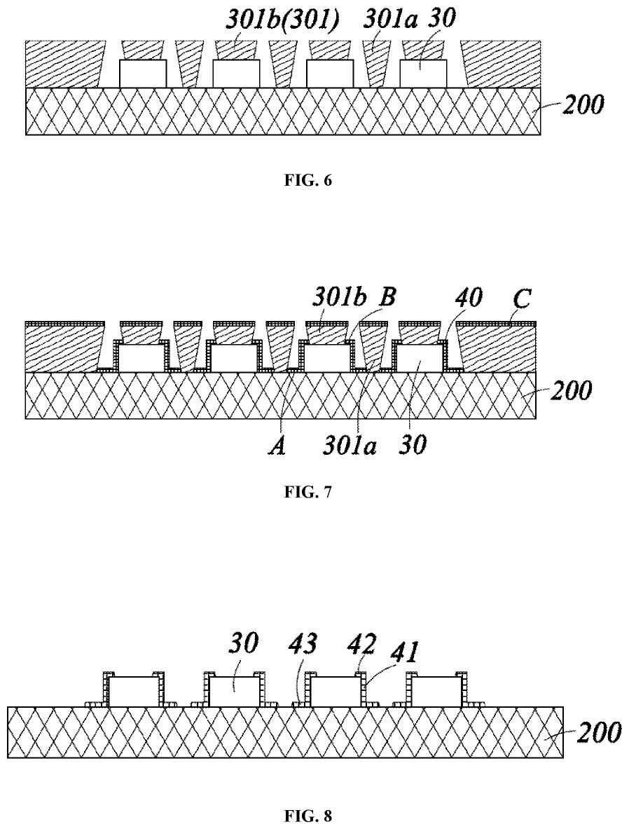

S1: with reference to FIG. 3, forming a redistribution layer 20 on a wafer substrate 200, where the redistribution layer 20 includes a plurality of metal bumps 30 distributed at intervals;

S2: with reference to FIGS. 4 to 8, forming seed layers 40 at least at the periphery of the metal bumps 30, and disconnecting the seed layers 40 of adjacent metal bumps 30 from each other; and

S3: cutting the wafer substrate 200 to form a plurality of package structures 100 independent of each other.

Here, the forming of the redistribution layer 20 may be completed by using sputtering, photoetching, electroplating, and etching processes sequentially.

The seed layers 40 of this embodiment have stable metallic characteristics, which may achieve effective protection of the side walls of the metal bumps 30 against metal-to-metal migration due to oxidation and corrosion of the metal bumps 30, thereby avoiding electrical leakage and failure of a chip and greatly increasing the reliability of the package structure 100.

In this embodiment, the step of “forming seed layers 40 at least at the periphery of the metal bumps 30” specifically includes:

coating a photoresist 300 above the wafer substrate 200, with reference to FIG. 4; and

removing a part of the photoresist 300 by exposing and developing processes to form a reserved photoresist 301, with reference to FIGS. 5 and 6, where the reserved photoresist 301 is located at least between the plurality of metal bumps 30,

specifically, this step including:

with reference to FIG. 5, placing a mask plate 400 with a plurality of apertures 401 above the photoresist 300;

illuminating the photoresist 300 with light through the plurality of apertures 401 to achieve exposure; and

with reference to FIG. 6, removing a part of the photoresist 300 by a developing process to form the reserved photoresist 301 in an inverted trapezoidal shape.

Here, a patterned transfer may be achieved in the photoresist 300 by the exposing and developing processes to remove undesired parts in the photoresist 300 and reserve desired parts.

It should be noted that “an inverted trapezoidal shape” means that in the direction from a position away from the wafer substrate 200 to a position close to the wafer substrate 200 (that is, from up to down), the reserved photoresist 301 is in an inverted trapezoidal shape, that is, the size of an upper end of the reserved photoresist 301 is greater than that of a lower end thereof.

In this embodiment, the photoresist 300 coated above the wafer substrate 200 encapsulates the plurality of metal bumps 30. At this time, the reserved photoresist 301 after exposure and development includes a first reserved photoresist 301a and a second reserved photoresist 301b. The first reserved photoresist 30a is located between the plurality of metal bumps 30, the second reserved photoresist 301b is located on the side of the metal bumps 30 away from the wafer substrate 100, that is, the second reserved photoresist 301b is located on the upper surface of the metal bumps 30, and the first reserved photoresist 301a and the second reserved photoresist 301b both have an inverted trapezoidal shape.

Of course, in other embodiments, only the first reserved photoresist 301a may be formed.

It can be understood that the reserved photoresist 301 may be rendered to be in the inverted trapezoidal shape by controlling the exposing and developing processes. For example, the shape of the reserved photoresist 301 after exposure and development is controlled by controlling the shape and position of the opening 401 on the mask plate 400, the placing position of the mask plate 400, the angle of illuminating light, the magnitude of energy, etc.

With reference to FIG. 7, the seed layers 40 are formed by a sputtering process. The seed layers 40 cover at least the periphery of the metal bumps 30.

Specifically, the seed layers 40 cover the periphery of the metal bumps 30, an area A of the wafer substrate 200 not covered by the first reserved photoresist 301a, an area B of the metal bumps 30 not covered by the second reserved photoresist 302a, and a surface C of the side of the reserved photoresist 301 away from the wafer substrate 200.

It should be noted that since the reserved photoresist 301 has the inverted trapezoidal shape, a side wall of the reserved photoresist 301 is inclined, so that the seed layers 40 cannot be formed at the inclined side wall by the sputtering process, that is to say, the seed layers 40 formed at this time is discontinuous.

With reference to FIG. 8, the reserved photoresist 301 and the seed layers 40 located at the reserved photoresist 301 are removed.

At this time, the reserved photoresist 301 is removed together with the seed layers 40 located thereabove.

That is to say, at this time, the seed layers 40 at the periphery of the metal bumps 30, in the area A of the wafer substrate 200 not covered by the first reserved photoresist 301a and in the area B of the metal bumps 30 not covered by the second reserved photoresist 302a are reserved, while the seed layers 40 on the surface C of the side of the reserved photoresist 301 away from the wafer substrate 200 are removed together with the reserved photoresist 301.

It can be understood that in this embodiment, the reserved photoresist 301 is formed in the inverted trapezoidal shape. With such a configuration, the following benefits are obtained: (1) the reserved photoresist 301 is directly formed between adjacent metal bumps 30, while the seed layers 40 (the third seed layers 43 here) subsequently formed between the adjacent metal bumps 30 are directly disconnected, omitting etching and disconnecting operations for the third seed layers 43; (2) the first reserved photoresist 301a between the adjacent metal bumps 30 has the inverted trapezoidal shape, which adapts to a tiny gap between the adjacent metal bumps 30; and (3) the formed seed layers 40 are discontinuous, so that undesired seed layers 40 may also be removed directly when the reserved photoresist 301 is removed, which is convenient and rapid.

Of course, in a wafer-level forming process, placed balls, plastic package layers, or the like may also be formed, and the finally formed package structure 100 may be a chip.

In summary, the seed layers 40 of this embodiment have stable metallic characteristics, which may achieve effective protection of the side walls of the metal bumps 30 against metal-to-metal migration due to oxidation and corrosion of the metal bumps 30, thereby avoiding electrical leakage and failure of the chip and greatly increasing the reliability of the package structure. In addition, the forming process of the seed layers 40 is simple and rapid.

It should be understood that although the Description is described according to the embodiments, not every embodiment includes only one independent technical solution. This presentation manner of the Description is only for clarity. A person skilled in the art should consider the Description as a whole, and technical solutions in all of the embodiments may also be properly combined to form other embodiments that will be understood by a person skilled in the art.

The above detailed description only aims to specifically illustrate the feasible embodiments of the present invention, and is not intended to limit the scope of protection of the present invention. Equivalent embodiments or modifications thereof made without departing from the spirit of the present invention shall fall within the scope of protection of the present invention.

What is claimed is:

1. A package structure, comprising a substrate and a redistribution layer, wherein the redistribution layer comprises a plurality of metal bumps distributed at intervals, at least the periphery of the metal bumps is covered with seed layers, and the seed layers of adjacent metal bumps are disconnected from each other.

2. The package structure according to claim 1, wherein the seed layers comprise first seed layers, second seed layers, and third seed layers that are connected, the first seed layers are located at the periphery of the metal bumps, the second seed layers are located on a surface of a side of the metal bumps away from the substrate, the third seed layers are located on the substrate, and adjacent ones of the third seed layers are disconnected from each other.

3. The package structure according to claim 2, wherein the second seed layers enclose to form openings, so as to expose the metal bumps.

4. The package structure according to claim 1, wherein the seed layers are titanium layers.

5. A forming method of a package structure, comprising the steps of:
forming a redistribution layer on a wafer substrate, wherein the redistribution layer comprises a plurality of metal bumps distributed at intervals;
forming seed layers at least at the periphery of the metal bumps, and disconnecting the seed layers of adjacent metal bumps from each other; and
cutting the wafer substrate to form a plurality of the package structures independent of each other.

6. The forming method according to claim 5, wherein the step of “forming seed layers at least at the periphery of the metal bumps” specifically comprises:
coating a photoresist above the wafer substrate;
removing a part of the photoresist by exposing and developing processes to form a reserved photoresist, wherein the reserved photoresist is located at least between the plurality of metal bumps;
forming seed layers by a sputtering process, wherein the seed layers cover at least the periphery of the metal bumps; and
removing the reserved photoresist and the seed layers located at the reserved photoresist.

7. The forming method according to claim 6, wherein the step of “removing a part of the photoresist by exposing and developing processes to form a reserved photoresist” specifically comprises:
placing a mask plate with a plurality of apertures above the photoresist;
illuminating the photoresist with light through the plurality of apertures to achieve exposure; and
removing a part of the photoresist by a developing process to form the reserved photoresist in an inverted trapezoidal shape.

8. The forming method according to claim 6, wherein the step of “coating a photoresist above the wafer substrate” specifically comprises:
coating a photoresist above the wafer substrate, wherein the photoresist encapsulates the plurality of metal bumps.

9. The forming method according to claim 8, wherein the step of “removing a part of the photoresist by exposing and developing processes to form a reserved photoresist, wherein the reserved photoresist is located at least between the plurality of metal bumps” specifically comprises:
removing a part of the photoresist by exposing and developing processes to form a reserved photoresist in an inverted trapezoidal shape, wherein the reserved photoresist comprises a first reserved photoresist located between the plurality of metal bumps and a second reserved photoresist located on a side of the metal bumps away from the wafer substrate.

10. The forming method according to claim 9, wherein the step of “forming seed layers by a sputtering process, wherein the seed layers cover at least the periphery of the metal bumps” specifically comprises:
forming the seed layers by a sputtering process, wherein the seed layers cover the periphery of the metal bumps, an area of the wafer substrate not covered by the first reserved photoresist, an area of the metal bumps not covered by the second reserved photoresist, and a surface of a side of the reserved photoresist away from the wafer substrate.
